(19) United States
(12) Patent Application Publication
(10) Pub. No.: US 2009/0229361 A1
(43) Pub. Date: Sep. 17, 2009

(54) Non-destructive testing box with integrated usb port

(75) Inventors: Vanessa Mengeling, Massy (FR); Didier Simonet, Leguevin (FR); Sébastien Rolet, Plaistance du Touch (FR)

Correspondence Address: Nixon Peabody LLP, 200 Page Mill Road, Palo Alto, CA, 94306, US

(73) Assignee: EUROPEAN AERONAUTIC DEFENCE AND SPACE COMPANY - EADS, Paris (FR)

(21) Appl. No.: 11/660,829

(22) PCT Filed: Aug. 24, 2005
(86) PCT No.: PCT/FR2005/050684

§ 371 Date: Aug. 27, 2008

(30) Foreign Application Priority Data
Aug. 25, 2004 (FR) 0451904

(51) Int. Cl. G01N 29/00; G01R 33/00

(52) U.S. Cl. 73/584; 324/200

(57) ABSTRACT

This invention relates to a non-destructive testing device comprising a testing box (2) connected to a measurement module (10).

This device also comprises a communication port (12) that simultaneously controls the testing box (2) through an external data processing device (20), the electrical power supply of said box (2) and the transfer of measurement data originating from said measurement module (10) to the external data processing device (20).

### TECHNICAL FIELD

The invention is in the domain of non-destructive testing, and more specifically relates to a non-destructive testing device that can be used in several different applications, particularly in the aeronautical and medical fields, for example for measuring the skin or bone thickness, etc.

### STATE OF PRIOR ART

Document [1] referenced to at the end of the description describes many non-destructive testing devices according to known prior art, namely acoustic, electromagnetic, mono or multi-sensor operation.

Such devices are usually connected to a measurement module comprising one or several sensors to make non-destructive measurements within the context of a given specific application.

Structurally, these devices comprise an electronic board composed of three parts, a signal emission or generation part, a reception part and a signal processing part. They are also provided with a cable to be connected to an electrical power supply source and a display screen.

Functionally, most of these devices are fixed in a given configuration without any possibility of change. Consequently, they are completely closed so that it is impossible for a user to modify the configuration to adapt them to other applications.

Furthermore, the presence of the display screen and the need to connect the testing devices to an external power supply source make them expensive and cumbersome and therefore not suitable for mobile use.

A first purpose of the invention is to make it possible to test and supply power to these devices by a single communication port.

A second purpose of the invention is to make these devices “open”, in other words reconfigurable as a function of applications without necessarily calling upon the manufacturer.

A third purpose of the invention is to miniaturize the device so as to make it more compact.

### PRESENTATION OF THE INVENTION

These purposes are achieved using a non-destructive testing device comprising a testing box connected to at least one measurement sensor.

The device according to the invention also comprises a communication port that simultaneously controls the testing box through an external data processing device, the electrical power supply of said box and the transfer of measurement data originating from said measurement module to the external data processing device.

In a first embodiment, the testing box comprises an ultrasound electronic testing module.

In a second embodiment, the testing box comprises an eddy current electronic testing module.

According to one special feature of the invention, said electronic test modules are configurable using the external processing device through the communication port.

In one preferred embodiment, said communication port is a USB port. In this case, the external data processing device is preferably a computer.

The use of a USB link means that the device according to the invention can be used as a lightweight and easily transportable computer peripheral so that it can be connected to any computer. This facilitates its configuration and reduces manufacturing costs.

The device according to the invention is thus a system simpler than devices according to prior art; it does not include any power supply, nor a screen, nor a complex connection, the assembly being managed by the external data processing device.

### BRIEF DESCRIPTION OF THE FIGURES

Other special features and advantages of the invention will appear through the following description given as a non-limitative example with reference to the appended FIGURE showing a device according to a preferred embodiment of the invention.

### DETAILED PRESENTATION OF PARTICULAR EMBODIMENTS

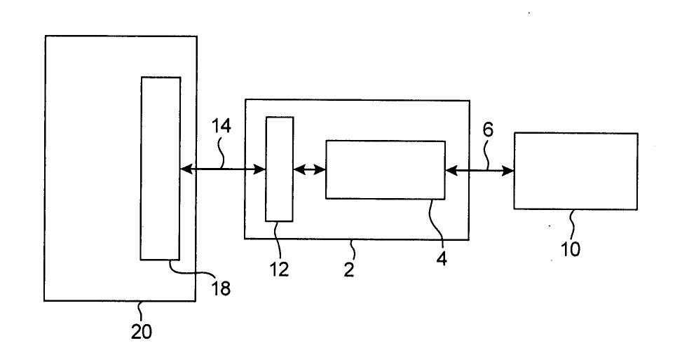

As shown in FIG. 1, the device according to the invention comprises a testing box 2, for example comprising an ultrasound or eddy current testing module 4 connected through a bi-directional link 6 to a detection module 10 comprising one or more non-destructive testing sensors. The link 6 is dedicated to excitation of the sensor(s) in the detection module 10 and reception of measurements originating from it (or them) through the electronic test module 4.

The device in FIG. 1 also comprises a USB port 12 making a USB connection 14 with a USB port 18 on a computer 20, for example a PC type computer. This USB link comprises a communication channel 14 carrying the electrical power supply of the testing box 2, transferring commands from the computer 20 to the box 2 to control configuration of the box and transferring measurement data originating from the sensor(s) to the computer.

Therefore, the device according to the invention is special in that it is tested and powered through the USB link.

Sensors in the detection module 10 are chosen as a function of the application field. Control of the box through the link 14 then consists of adapting operating parameters (sensor excitation frequency, intensity of excitation currents, etc.) of the electronic testing module 4 (ultrasound or eddy current) to the envisaged non-destructive testing application.

It is thus possible to configure the device according to the invention for several modes starting from the same computer. For example, such a device may be used with different materials to measure the thickness of a sheet metal plate, to detect cracks or even to detect corrosion.

In one example embodiment, the computer is an industrial tablet PC on which software for measuring a metallic thickness is installed, the sensor being an ultrasound sensor with a central frequency of 10 MHz.

Integration of a USB port into the testing box provides a means of making a non-destructive testing device for which the weight varies between 200 g and 2 kg depending on the computer type used, and a size of about 200 mm×150 mm×30 mm. The testing box weighs about 130 g, and its size is about 120 mm×60×30 mm. The weight of the sensor is about 10 g.

### REFERENCES

[1]<<Nondestructive Material testing with ultrasonics-Introduction to Basic Principle >> by Michael Berke (Krautkramer, September 2000, Number 09, Vol. 5).
[2]<<Le protocole USB>> (The USB protocol) by Fabien Chevalier, Sylvain Richerioux, and Nicolas Sinégre (Internet address: <<www.rennes.supelec.fr/ren/fi/elec/docs/usb/usb.html, April 2003).

1. Non-destructive testing device comprising a testing box (2) connected to a measurement module (10), characterized in that it also comprises a communication port (12) that simultaneously controls the testing box (2) through an external data processing device (20), the electrical power supply of said box (2) and the transfer of measurement data originating from said measurement module (10) to the external data processing device (20), said testing box (2) further comprising an ultrasound electronic testing module (4) and/or an eddy current electronic testing module (4).

2. Device according either to claim 1, said electronic test module (4) is configurable using the external processing device (20) through the communication port (12).

3. Device according to claim 1, characterized in said communication port (12) is a USB port.

4. Device according, to claim 1, characterized in that the external data processing device (20) is a computer.

5. Device according to claim 1, characterized in that said communication port (12) is a USB port.

6. Device according to claim 1, characterized in that the external data processing device (20) is a computer.

7. Device according to claim 1, characterized in that the measurement module (10) comprises at least one ultrasound sensor and/or at least one eddy current sensor.
